(19) United States
(12) Patent Application Publication
(10) Pub. No.: US 2001/0016262 A1
(43) Pub. Date: Aug. 23, 2001

(54) Method of coating substrate and coated article

(76) Inventors: Takayuki Toyoshima, Osaka (JP); Toshiaki Anzaki, Osaka (JP)

Correspondence Address: SUGHRUE, MION, ZINN, MACPEAK & SEAS, PLLC, 2100 Pennsylvania Avenue, N.W., Washington, DC, 20037, US

(21) Appl. No.: 09/753,620

(22) Filed: Jan. 4, 2001

(30) Foreign Application Priority Data
Jan. 7, 2000 (JP) P. 2000-001229

(51) Int. Cl. B32B 27/00; C23C 14/32

(52) U.S. Cl. 428/428; 428/425.5; 428/698; 204/192.15; 204/192.23

(57) ABSTRACT

A silicon target material is sputtered in a vacuum chamber having a controlled vacuum atmosphere in a reactive sputtering gas containing oxygen and nitrogen while varying the composition of the sputtering gas during the sputtering to thereby form a coating having a refractive index gradient due to a composition gradient in the thickness direction thereof on the substrate. The coating reduces the surface reflectance of glass to one-twentieth in a wavelength region of from 450 to 650 nm.

### FIELD OF THE INVENTION

This invention relates to a method of coating a substrate and a coated article obtained by the method. More particularly, it relates to a coating method suitable to form an antireflection coating and an article having an antireflection coating obtained by the method.

### BACKGROUND OF THE INVENTION

Vacuum film formation techniques, such as vacuum evaporation and sputtering, have conventionally been adopted to form an optical coating, particularly an antireflection coating, on a substrate to provide the substrate with an optical function, particularly an antireflection function. Since precise film thickness control is demanded for obtaining a higher antireflection function, vacuum film formation techniques have been preferred to chemical film formation techniques, such as a sol-gel process, for their excellent controllability on film thickness.

To achieve high antireflection performance by sputtering, it is necessary to build up a multilayer structure comprising a high-refractive layer and a low-refractive layer. Formation of such a multilayer antireflection coating needs a large-sized sputtering system having at least two sputtering cathodes, which incurs an increased cost.

### SUMMARY OF THE INVENTION

An object of the present invention is to provide a method of coating a substrate with a highly functional coating (a low reflection coating) without requiring a large-sized film formation system. That is, the object is to provide a monolayer coating which is equal or superior in function (low reflection) to a conventional multilayer coating.

The present invention provides a method of coating a substrate to form a coating having a composition gradient in the thickness direction which comprises sputtering a target material in a vacuum chamber having a controlled vacuum atmosphere to form a coating comprising the target material, wherein the composition of a sputtering gas introduced into the vacuum chamber is varied during the sputtering.

The invention has been reached as a result of extensive investigation as to how to obtain a high optical function economically with a simplified film structure by forming an optical thin film, typically exemplified by an antireflection coating, on a substrate by sputtering. The present inventors have found that the above problem is settled by changing the film constituent components in the thickness direction and that such can be achieved by varying the composition of the sputtering gas introduced into the vacuum chamber. It is preferred for the sputtering gas to have its composition varied continuously from the substantial commencement to the substantial completion of coating.

In a preferred embodiment of the invention, the target material is silicon or a silicon compound, and the sputtering gas is a mixed gas of argon, oxygen and nitrogen. In this embodiment, the sputtering is reactive sputtering. Where silicon is used as a target, the resulting coating comprises silicon oxide (e.g., SiO₂), silicon nitride, or a composition intermediate therebetween. Where silicon dioxide or quartz glass is used as a target, and nitrogen is used as a reactive sputtering gas, the resulting coating comprises SiOₓN_{y}.

The above-described preferred embodiment provides a coating which has a content of an oxide, oxynitride or nitride of silicon varied in its thickness direction and shows no substantial absorption of visible light.

In another preferred embodiment of the invention, the ratio of oxygen and nitrogen of the mixed gas as a reactive sputtering gas is varied. Where silicon is used as a target, and oxygen and nitrogen are used as reactive sputtering gas components in this embodiment, the resulting coating can have the refractive index distributed broadly substantially from 1.48 (the refractive index of SiO₂) to 2.1 (the refractive index of Si₃N₄).

It is preferred that the composition of the sputtering gas is varied according to the reflectance or the transmittance of the substrate while being coated. The control for continuously changing the gas composition during film formation is conveniently effected by means of an optical transmittance monitor or an optical reflectance monitor. That is, the reflectance or transmittance of the coating while being formed is measured, and the feed rate(s) of oxygen and/or nitrogen is(are) controlled by a feedback control system based on the measurements, thereby to suppress fluctuations of optical characteristics due to slight variations of the coating rate among batches.

In order to obtain a highly functional optical coating, an elaborate optical design is required. It is preferred for forming a coating according to such an optical design that the power applied to the cathode be controlled by a feedback control system connected to a calculator while monitoring the optical characteristics of the coating while being formed by means of a transmittance or reflectance monitor. By this manipulation, it is possible to sufficiently suppress fluctuations of optical characteristics due to slight variations of the coating rate among batches.

The present invention also provides an article coated by the method of the invention which has a smaller refractive index in the part farther from the substrate than in the part nearer to the substrate. The article according to the invention has a reduced visible light reflectance as compared with the reflectance of the substrate itself. The antireflection coating of the article has its composition varied continuously in the thickness direction. Since the compositional variation can be made by variation of the composition of the reactive sputtering gas, there is no need to use a large-sized sputtering apparatus having a plurality of cathodes.

The article of the invention preferably includes one whose coating is made up of silicon, oxygen, and nitrogen, in which the nitrogen content decreases and the oxygen content increases in the thickness direction from the substrate side to the surface of the coating. The coating of this article is transparent and shows no substantial absorption of visible light.

The substrate which can be used in the invention usually includes a glass plate. According to the invention, it is possible to reduce the surface reflectance of glass, such as window glass, glass for liquid crystal displays, and glass for plasma display panels, which usually has a refractive index of about 1.52 and a surface reflectance of 4%, to 1% or smaller. The present invention is also applicable to other optical lenses.

It is preferred for the antireflection coating of the article to have a controlled refractive index distribution in its thickness direction so as to have a surface reflectance of 0.2% or less.

### BRIEF DESCRIPTION OF THE DRAWINGS

FIG. 1 is a cross section of an article according to the invention.

FIG. 2 illustrates the refractive index distribution of the coating of FIG. 1 in its thickness direction.

Description of the Reference Numerals and Signs:

1 . . . article of the invention

2 . . . substrate

3 . . . coating with refractive index gradient in thickness direction

### DETAILED DESCRIPTION OF THE INVNETION

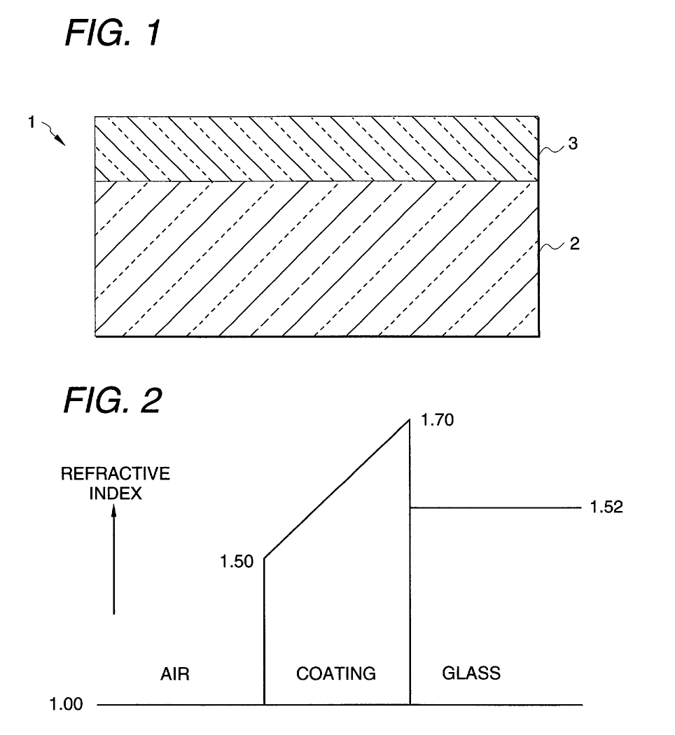

FIG. 1 is a cross section of a coated article according to the invention. The article 1 shown in FIG. 1 comprises a glass plate 2 having on one side thereof an antireflection coating 3 having a refractive index gradient in its thickness direction. FIG. 2 shows the refractive index distribution of the coating of the article obtained in Example 1. The part of the coating 3 in contact with the substrate (glass) 2 is rich in silicon oxynitride, having a refractive index of 1.70 at a wavelength of 550 nm, while the part of the coating 3 in contact with air, i.e., the surface of the coating 3 is rich in silicon dioxide, having a refractive index of 1.50 at 550 nm.

In order to secure a low reflectance over a broad range of wavelength, it is preferred that the refractive index of the part of the coating 3 in the vicinity of the glass substrate 2 be greater than that of the glass substrate 2 and that the refractive index in the vicinity of the surface of the coating 3 be smaller than that of the glass substrate 2.

Any of known sputtering apparatus can be used to carry out the present invention. That is, a sputtering apparatus having a vacuum chamber of which the vacuum atmosphere can be controlled through a vacuum port led to a vacuum pump and a sputtering gas inlet led to a gas feed mechanism can be used. The present invention can be carried out in a known manner, such as a DC sputtering method and an RF sputtering method. A known MF method is also applicable to the present invention, in which a pair of cathodes are disposed nearby, and the targets attached to the two cathodes are co-sputtered while alternately inverting the polarity of the two cathodes at an inversion frequency of 10 kHz to 1 MHz so that one of the cathodes may be a negative electrode when the other is a positive electrode while the former may be a positive electrode when the latter is a negative electrode.

The present invention will now be illustrated in greater detail with reference to Examples. In every Example, a transparent soda-lime glass plate used as a windowpane was used as a substrate. The glass plate had a transmittance of about 92% and a surface reflectance of about 4%.

### EXAMPLE 1

RF sputtering was carried out by using quartz glass (SiO₂) as a target and an argon/nitrogen mixed gas as a reactive sputtering gas to form a coating on the substrate. The argon to nitrogen feed ratio, which started with 20%/80%, was gradually varied by decreasing the nitrogen gas feed with the progress of coating, finally reaching 100% argon at around the end of sputtering so that the coating might have a composition represented by formula: SiOₓN_{y} (O≦x≦2, O≦y≦4/3).

The resulting coated glass plate was found to have a surface reflectance of 0.2% at a wavelength of 550 nm, providing confirmation that a marked antireflection function had been afforded to the substrate. Virtually the same reflectance was obtained at wavelengths of 450 nm and 650 nm, which verifies that the antireflection coating was effective over a broad range of wavelength. The coating was found to have a refractive index of 1.5 in the vicinity of the surface thereof and of 1.7 in the vicinity of the substrate.

### EXAMPLE 2

Sputtering was carried out by an MF method by using silicon (Si) as target on each of two cathodes and, as a reactive sputtering gas, an argon/nitrogen mixed gas in the beginning of sputtering and an argon/oxygen mixed gas from the stage near to the end of sputtering to form a coating on the substrate. The nitrogen gas feed was gradually decreased with the progress of coating, while continuously increasing the oxygen gas feed so as to form a monolayer coating represented by formula: SiOₓN_{y} (O≦x≦2, O≦y≦4/3) wherein the nitrogen content decreased, and the oxygen content increased from the substrate side to the surface side.

The resulting coated glass plate was found to have a surface reflectance of 0.2% at a wavelength of 550 nm, providing that the reflectance of the glass substrate (4%) was greatly reduced. Virtually the same reflectance was obtained at wavelengths of 450 nm and 650 nm, which verifies that the antireflection coating was effective over a broad range of wavelength.

It has now been confirmed that a coating having an antireflection function can be formed on a glass substrate by using a single cathode having a quartz glass target attached thereto while providing a refractive index gradient in the thickness direction of the coating. It has also been confirmed that such an antireflection coating can be obtained by an MF sputtering system using a pair of cathodes. The antireflection coating of the present invention has been proved to have a low reflectance over a broad range of wavelength.

According to the present invention, a substrate can be provided with a coating having a composition gradient in its thickness direction by sputtering simply by varying the composition of the sputtering gas introduced into the sputtering apparatus.

According to the present invention, the surface reflectance of a substrate can be reduced by providing an antireflection coating having a monolayer structure whose refractive index decreases toward the surface thereof and exhibiting an antireflection function over a broad visible region.

The article having an antireflection coating according to the present invention can be produced economically by use of a relatively inexpensive sputtering apparatus having a single cathode.

What is claimed is:

1. A method of coating a substrate comprising sputtering a target material in a vacuum chamber having a controlled vacuum atmosphere to form a coating comprising said target material, wherein the composition of a sputtering gas introduced into said vacuum chamber is varied during the sputtering to form a coating having a composition gradient in the thickness direction thereof on said substrate.

2. The method of coating a substrate according to claim 1, wherein said target material is silicon or a silicon compound, and said sputtering gas is a mixed gas of argon, oxygen and nitrogen.

3. The method of coating a substrate according to claim 2, wherein the ratio of oxygen and nitrogen of said mixed gas is varied.

4. The method of coating a substrate according to claim 1, wherein the composition of said sputtering gas is varied according to the reflectance or the transmittance of the substrate while being coated.

5. An article comprising a substrate and a coating which is obtained by the method according to claim 1 and has a smaller refractive index in the part farther from the substrate than in the part nearer to the substrate.

6. The article according to claim 5, wherein said coating comprises silicon, nitrogen and oxygen and has a nitrogen content decreased and an oxygen content increased in the thickness direction thereof from the substrate side toward the surface thereof.

7. The article according to claim 6, which has a reflectance of 0.2% or less for visible light incident on the coating side.
